(19) United States
(12) Patent Application Publication
(10) Pub. No.: US 2013/0161765 A1
(43) Pub. Date: Jun. 27, 2013

(54) MIS TYPE SEMICONDUCTOR DEVICE AND PRODUCTION METHOD THEREFOR

(71) Applicant: TOYODA GOSEI CO., LTD., Kiyosu-shi (JP)

(72) Inventors: Takahiro SONOYAMA, Kiyosu-shi (JP); Toru OKA, Kiyosu-shi (JP)

(73) Assignee: TOYODA GOSEI CO., LTD., Kiyosu-shi (JP)

(21) Appl. No.: 13/722,967

(22) Filed: Dec. 20, 2012

(30) Foreign Application Priority Data
Dec. 26, 2011 (JP) 2011-283701
Dec. 26, 2011 (JP) 2011-283702

(51) Int. Cl. H01L 29/40; H01L 29/51

(52) U.S. Cl. CPC H01L 29/401; H01L 29/518
USPC 257/411; 438/591

(57) ABSTRACT

The present invention provides a MIS type semiconductor device having a ZrOₓN_{y} gate insulating film wherein threshold voltage is stable. In the MIS type semiconductor device with an operating voltage of 5 V or more, having a gate insulating film on a Si semiconductor layer and a gate electrode on the gate insulating film, the gate insulating film is formed of ZrOₓN_{y} (here, x and y satisfy the following conditions: x>0, y>0, 0.3≦y/x≦10, and 1.5≦0.55x+y≦1.7). The MIS type semiconductor device having such gate insulating film can be stably operated because the threshold voltage does not fluctuate even if a large voltage is applied.

### BACKGROUND OF THE INVENTION

1. Field of the Invention

The present invention relates to a MIS type semiconductor device with an operating voltage of 5 V or more, having a gate insulating film formed of ZrOₓN_{y} (zirconium oxynitride) on a semiconductor layer and a gate electrode on the gate insulating film, and also relates to its production method.

2. Background Art

With further miniaturization of semiconductor devices in recent years, thinner insulating film of transistor gate is in demand. However, there is a problem that when the conventionally used SiO₂ film is thinned, the leak current increases. Therefore, thicker film is obtained by using a high-k (high dielectric constant) material in place of SiO₂. A high-k material includes HfO₂, ZrO₂, TiO₂, HfOₓN_{y}, ZrOₓN_{y}, or similar materials. Specifically, a MIS (Metal-Insulator-Semiconductor) type semiconductor device having a gate insulating film formed of ZrOₓN_{y} is disclosed in patent documents 1 to 3.

Patent document 1 discloses a semiconductor device having a gate insulating film on a semiconductor substrate and a gate electrode on the gate insulating film, wherein the gate insulating film is formed of Zr₂ON₂ or ZrO₂₋₂ₓN_{4x/3} (where ⅜<x<¾). It is also disclosed that the gate insulating film is a single crystal or polycrystal. Patent document 1 describes that a Zr₂ON₂ gate insulating film is formed by sputtering a Zr₂ON₂ ceramic target. It is also described that argon is used as a sputtering gas, a substrate temperature is from 600° C. to 800° C., and a sputtering gas pressure is from 0.5 Pa to 0.2 Pa.

Patent document 2 discloses a MIS type semiconductor device having a ZrO₂ gate insulating film containing nitrogen, wherein the gate insulating film has a higher nitrogen concentration on the channel side than that on the gate electrode side, and the gate insulating film has a nitrogen concentration of 10²⁰/cm³ to 10²¹/cm³ on the channel side. It is also described that the gate insulating film is formed by sputtering in a mixture gas of nitrogen and oxygen diluted with argon gas at a temperature from room temperature to 800° C. and a pressure from 0.1 mPa to 1 kPa. There is no particular description of which state the gate insulating film is in: single crystal, polycrystal or amorphous.

Patent document 3 discloses a MIS type semiconductor device in which a chemical oxide layer, a high-k dielectric layer, a lower metal layer, a capturing metal layer, an upper metal layer, and a polycrystalline semiconductor layer are sequentially deposited on a semiconductor substrate. It is described that Si or Group III-V semiconductor may be used as a semiconductor substrate. The high-k dielectric layer may be formed of ZrOₓN_{y} (0.5≦x≦3, 0≦y≦2). There is no particular description of which state the high-k dielectric material is in: single crystal, polycrystal, or amorphous. Although it is described that the high-k dielectric layer may be formed by CVD or ALD, there is no particular description of formation of the high-k dielectric layer by sputtering.

Patent document 1: Japanese Patent Application Laid-Open (kokai) No. 2005-44835

Patent document 1: Japanese Patent Application Laid-Open (kokai) No. 2005-217159

Patent document 1: Japanese Patent Application Laid-Open (kokai) No. 2011-3899

The inventors have studied to downsize the MIS type power devices by employing a high-k dielectric gate insulating film formed of ZrOₓN_{y}. However, it was found that when the gate insulating film is formed of ZrOₓN_{y}, the threshold gate voltage fluctuates due to high applied voltage, resulting in an unstable operation, at certain composition ratios x and y of ZrOₓN_{y}. Such a problem of threshold voltage fluctuation is neither described nor suggested in the patent documents 1 to 3.

### SUMMARY OF THE INVENTION

In view of the foregoing, an object of the present invention is to stabilize the threshold voltage in a MIS type semiconductor device having a gate insulating film formed of ZrOₓN_{y} on a semiconductor layer and a gate electrode on the gate insulating film.

In a first aspect of the present invention, there is provided a MIS type semiconductor device with an operating voltage of 5 V or more, comprising a gate insulating film formed of ZrOₓN_{y} on a semiconductor layer and a gate electrode on the gate insulating film, wherein the gate insulating film is in amorphous state, and composition ratios x and y of ZrOₓN_{y} satisfy the following conditions: x>0, y>0, and 0.3≦y/x≦10.

The semiconductor layer may be, for example, a Si layer, a Group III nitride semiconductor layer, a Group III-V semiconductor layer, a Group II-VI compound semiconductor layer, or a SiC layer. The Group III nitride semiconductor layer includes a GaN layer, an AlGaN layer, an InGaN layer, an AlN layer, or an AlGaInN layer. The Group III-V semiconductor layer includes a GaAs layer, a GaP layer, or a GaInP layer. The Group II-VI compound semiconductor layer includes a ZnO layer. The semiconductor layer may be doped with an n-type impurity or a p-type impurity. Moreover, the semiconductor layer may be a semiconductor substrate itself or a semiconductor layer deposited on a semiconductor substrate or an insulating substrate. The semiconductor layer may comprise a plurality of layers having different materials, composition ratios, conductive types, and impurity concentrations.

The gate insulating film may comprise a plurality of layers having different composition ratios so long as the composition ratios x and y of ZrOₓN_{y} satisfy the range as indicated above.

The semiconductor layer and the gate insulating film may be directly in contact with each other, or have an insulating film between the semiconductor layer and the gate insulating film. In this case, the insulating film may be formed of SiO₂, SiₓN_{y}, ZrO₂ or similar materials.

The gate insulating film and the gate electrode may be directly in contact with each other. An insulating film or a metal film may be formed between the gate insulating film and the gate electrode.

More preferably, the composition ratios x and y of ZrOₓN_{y} satisfy the y/x range of 1≦y/x≦5. Also, x and y preferably satisfy the range of 1.5≦0.55x+y≦1.7. When x and y fall within this range, fluctuation in threshold voltage of the MIS type semiconductor device can be further suppressed, thereby improving the operation stability.

Further if x and y of the gate insulating film of the present invention is limited to a range of x≦0.5, fluctuation in threshold voltage can be further suppressed, thereby improving the operation stability.

The MIS type semiconductor device of the present invention is effective particularly when the operating voltage is 10 V or more. At such a high operating voltage, the MIS type semiconductor device of the present invention can suppress fluctuation in threshold voltage.

Moreover, the MIS type semiconductor device of the present invention can be suitably employed in a power semiconductor device, and can be applied to a semiconductor device such as MISFET, HFET, and IGBT.

A second aspect of the present invention is drawn to a specific embodiment of the MIS type semiconductor device according to the first aspect, wherein 1.5≦0.55x+y≦1.7 is further satisfied.

A third aspect of the present invention is drawn to a specific embodiment of the MIS type semiconductor device according to the first or the second aspect, wherein x and y satisfy 1≦y/x≦5.

A fourth aspect of the present invention is drawn to a specific embodiment of the MIS type semiconductor device according to any one of the first to the third aspect, wherein x≦0.5.

A fifth aspect of the present invention is drawn to a specific embodiment of the MIS type semiconductor device according to any one of the first to the fourth aspect, wherein the gate insulating film is formed directly in contact with on the semiconductor layer.

A sixth aspect of the present invention is drawn to a specific embodiment of the MIS type semiconductor device according to any one of the first to the fifth aspect, wherein the semiconductor layer is a Group III nitride semiconductor layer.

A seventh aspect of the present invention is drawn to a specific embodiment of the MIS type semiconductor device according to the first to the sixth aspect, wherein the operating voltage is 10 V or more.

In an eighth aspect of the present invention, there is provided a method for producing a MIS type semiconductor device, the method comprising forming a ZrOₓN_{y} gate insulating film on a semiconductor layer by sputtering method, forming a gate electrode on the gate insulating film, and wherein the insulating film is formed in amorphous state, and x and y satisfy the following conditions: x>0, y>0, 0.3≦y/x≦10, and 1.5≦0.55x+y≦1.7, using a Zr metal target, and flowing a mixture gas containing nitrogen gas and oxygen gas at a room temperature in the sputtering method.

A ninth aspect of the present invention is drawn to a specific embodiment of the production method according to the eighth aspect, wherein x and y further satisfy 1.5≦0.55x+y≦1.7.

A tenth aspect of the present invention is drawn to a specific embodiment of the production method according to the eighth or the ninth aspect, wherein the gate insulating film is formed so that x and y satisfy 1≦y/x≦5.

An eleventh aspect of the present invention is drawn to a specific embodiment of the production method according to any one of the eighth to the tenth aspect, wherein the gate insulating film is formed so as to satisfy x≦0.5.

A twelfth aspect of the present invention is drawn to a specific embodiment of the production method according to any one of the eighth to the eleventh aspect, wherein the gate insulating film is formed directly on the semiconductor layer.

A thirteenth aspect of the present invention is drawn to a specific embodiment of the production method according to any one of the eighth to the twelfth aspect, wherein the semiconductor layer is a Group III nitride semiconductor layer.

A fourteenth aspect of the present invention is drawn to a specific embodiment of the production method according to any one of the eighth to the thirteenth aspect, wherein the MIS type semiconductor device has an operating voltage of 5 V or more, or 10 V or more.

In an fifteenth aspect of the present invention, there is provided a method for producing a MIS type semiconductor device, the method comprising forming a ZrOₓN_{y} gate insulating film on a semiconductor layer by sputtering method, forming a gate electrode on the gate insulating film, and wherein the insulating film is formed using a Zr metal target, and flowing a mixture gas containing nitrogen gas and oxygen gas at a room temperature in the sputtering method, and the ratio of oxygen gas flow rate to nitrogen gas flow rate, i.e., oxygen gas flow rate/nitrogen gas flow rate, is from 0.012 to 0.36.

The ratio of oxygen gas flow rate to nitrogen gas flow rate is preferably from 0.036 to 0.36. Thus, fluctuation in threshold voltage can be further suppressed, thereby further improving the operation stability of the MIS type semiconductor device.

Moreover, preferably the nitrogen gas flow rate is from 4.3 to 17 sccm, and the oxygen gas flow rate is from 0.1 to 3.0 sccm. When they fall within these ranges, a gate insulating film can be formed with good controllability of oxygen composition ratio x and nitrogen composition ratio y in ZrOₓN_{y}.

A sixteenth aspect of the present invention is drawn to a specific embodiment of the production method according to the fifteenth aspect, wherein the ratio of oxygen gas flow rate to nitrogen gas flow rate is from 0.036 to 0.36.

A seventeenth aspect of the present invention is drawn to a specific embodiment of the production method according to the fifteenth or the sixteenth aspect, wherein the nitrogen gas flow rate is from 4.3 to 17 sccm, and the oxygen gas flow rate is from 0.1 to 3.0 sccm.

An eighteenth aspect of the present invention is drawn to a specific embodiment of the production method according to any one of fifteenth to the seventeenth aspect, wherein the sputtering method is ECR sputtering method.

A nineteenth aspect of the present invention is drawn to a specific embodiment of the production method according to any one of fifteenth to the eighteenth aspect, wherein the gate insulating film is formed directly in contact with on the semiconductor layer.

A twelfth aspect of the present invention is drawn to a specific embodiment of the production method according to any one of fifteenth to the nineteenth aspect, wherein the semiconductor device has an operating voltage of 5 V or more, or 10 V or morer.

According to the present invention, even if a large voltage is applied to a MIS type semiconductor device, fluctuation in threshold voltage is suppressed, enabling stable operation. It is not clear why such effect of stable threshold voltage is achieved by the gate insulating film of the present invention. However, it is considered because a density of energy level generated by oxygen deficiency in the gate insulating film is reduced by nitrogen of the gate insulating film. The present invention is effective for the MIS type semiconductor device with an operating voltage of 5 V or more, particularly 10 V or more, and can be applied to a power semiconductor device. The gate insulating film according to the present invention is stable in heat treatment, and can be kept in amorphous state without being crystallized up to about 800° C. Therefore, the limitation for a temperature is reduced in the heat treatment process after formation of the gate insulating film, thereby allowing higher flexibility of the production process compared to the conventional production process.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a cross-sectional view showing the configuration of a MIS type semiconductor device according to Embodiment 1;

FIGS. 2A and 2B are sketches showing a process for producing the MIS type semiconductor device according to Embodiment 1;

FIG. 3 is a graph showing the Capacitance-Voltage characteristic of the MIS type semiconductor device according to Embodiment 1;

FIG. 4 is a graph showing the Capacitance-Voltage characteristic of a MIS type semiconductor device according to a comparative example;

FIG. 5 is a graph showing oxygen composition ratio and nitrogen composition ratio of a gate insulating film 11;

FIG. 6 is a graph showing nitrogen atom concentration/oxygen atom concentration of a gate insulating film 11;

FIG. 7 shows the configuration of a HFET according to Embodiment 2;

FIGS. 8A to 8E are sketches showing a process for producing a HFET according to Embodiment 2; and

FIG. 9 shows the configuration of a HFET according to Embodiment 3.

### DETAILED DESCRIPTION OF PREFERRED EMBODIMENTS

Specific embodiments of the present invention will next be described with reference to the drawings. However, the present invention is not limited to the embodiments.

### Embodiment 1

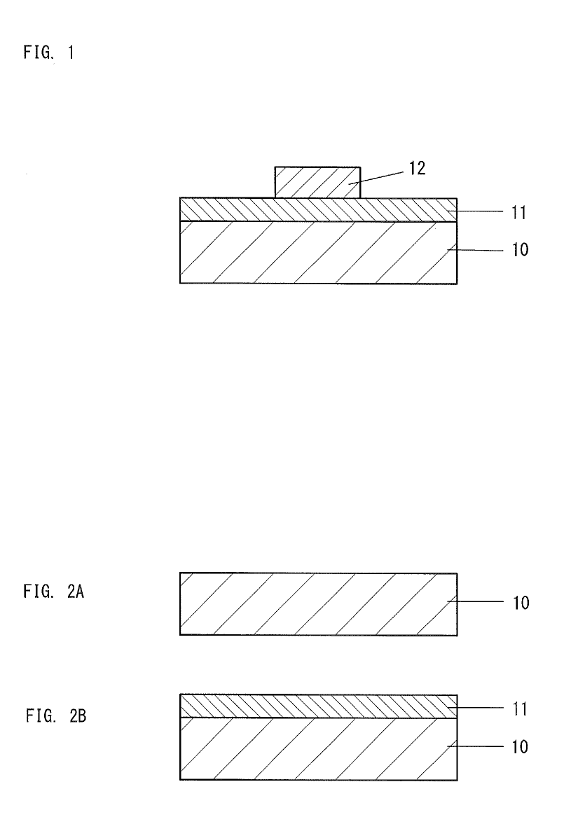

FIG. 1 is a cross-sectional view showing the configuration of a MIS type semiconductor device according to Embodiment 1. The MIS type semiconductor device according to Embodiment 1 includes a semiconductor layer 10, a gate insulating film 11 formed in contact with on the semiconductor layer 10, and a gate electrode 12 formed in contact with on a region of the gate insulating film 11.

The semiconductor layer 10 is an n-type Si substrate having a thickness of 600 μm. The semiconductor layer may be, for example, a Group III nitride semiconductor layer, a Group III-V semiconductor layer, a Group II-VI compound semiconductor layer, or a SiC layer, in place of Si. The Group III nitride semiconductor layer is a layer formed of, for example, GaN, AlN, AlGaN, InGaN, or AlGaInN. The Group III-V semiconductor layer is a layer of, for example, GaAs, GaP, or GaInP. The Group II-VI compound semiconductor layer is, for example, a ZnO layer. Moreover, the conduction type of the semiconductor layer 10 is not limited to n-type, and may be p-type or i-type (intrinsic). The semiconductor layer 10 is not limited to a single layer, and may comprise a plurality of layers. For example, it may have a structure in which a plurality of layers having different materials, conduction types, composition ratios, or impurity concentrations are deposited. The semiconductor layer 10 may be a semiconductor substrate itself or a layer deposited on a semiconductor substrate or an insulating substrate.

The gate insulating film 11 is formed of amorphous ZrOₓN_{y} (here, x and y satisfy the following conditions: x>0, y>0, 0.3≦y/x and 1.5≦0.55x+y≦1.7) having a thickness of 75 nm.

The gate insulating film 11 may be in contact with on the semiconductor layer 10 as in Embodiment 1, or may be formed on the semiconductor layer 10 via another insulating film. For example, an insulating film of SiO₂, SiₓN_{y}, ZrO₂ or similar materials may be formed between the semiconductor layer 10 and the gate insulating film 11.

Polysilicon or tungsten (W) may be used as a gate electrode 12. The gate electrode 12 may be formed directly in contact with on the gate insulating film 11 as in Embodiment 1, or may be formed on the gate insulating film 11 via another insulating film. For example, another insulating film or a metal layer may be formed between the gate insulating film 11 and the gate electrode 12.

In the MIS type semiconductor device according to Embodiment 1, the gate insulating film 11 is formed of amorphous ZrOₓN_{y} (here, x and y satisfy the following conditions: x>0, y>0, 0.3≦y/x≦10, and 1.5≦0.55x+y≦1.7). Therefore, even if a 5 V or larger voltage is applied, fluctuation in threshold voltage is suppressed, enabling stable operation. Thus, the MIS type semiconductor device according to Embodiment 1 can be stably operated at an operating voltage of 5 V or more, particularly even at 10 V or more. Since stable operation is possible at such a high operating voltage, the MIS type semiconductor device according to Embodiment 1 is suitable for use as a power semiconductor device such as FET, HFET, and IGBT. The gate insulating film 11 of the MIS type semiconductor device according to Embodiment 1 can be kept in amorphous state without being crystallized even through a heat treatment up to about 800° C. Therefore, the MIS type semiconductor device according to Embodiment 1 is also superior in thermal stability.

More preferably, the composition ratio of nitrogen to oxygen y/x of the gate insulating film 11 satisfies 1≦y/x≦5. Fluctuation in threshold voltage is further suppressed, enabling more stable operation.

The oxygen composition ratio x may further satisfy x≦0.5. Also in the MIS type semiconductor device according to Embodiment 1 having the gate insulating film 11 which satisfies such a composition range of x and y, fluctuation in threshold voltage is suppressed, enabling stable operation.

Next will be described a process for producing the MIS type semiconductor device according Embodiment 1.

Firstly, a semiconductor layer 10, which is an n-type Si substrate, was prepared. The surface of the semiconductor layer 10 was cleaned using acetone, IPA (isopropyl alcohol), and ultrapure water in this order to thereby remove oil content therefrom. Then, the semiconductor layer 10 was immersed in a buffered hydrogen fluoride (BHF) solution, thereby to remove an oxide film naturally formed on the surface of the semiconductor layer 10 (FIG. 2A).

Subsequently, on the cleaned semiconductor layer 10, a ZrOₓN_{y} gate insulating film 11 was formed by ECR (Electron Cyclotron Resonance) sputtering method (FIG. 2B). Sputtering was performed using a Zr metal target in a mixture gas of nitrogen and oxygen mixed with argon gas. The substrate temperature was a room temperature (1° C. to 30° C.), the pressure was from 0.07 Pa to 0.2 Pa, the RF power was 500 W, and the microwave power was 500 W. The argon gas flow rate was from 15 sccm to 30 sccm, the oxygen gas flow rate was from 0.1 sccm to 3.0 sccm, and the nitrogen gas flow rate was from 4.3 sccm to 17 sccm. The oxygen composition ratio and the nitrogen composition ratio of the gate insulating film 11 can be adjusted by the oxygen gas flow rate and the nitrogen gas flow rate, respectively. The ratio of the oxygen gas flow rate to the nitrogen gas flow rate, i.e., the oxygen gas flow rate/the nitrogen gas flow rate, was from 0.012 to 0.36.

In the above ECR sputtering method, argon gas was used as a carrier gas. However, other inert gas such as xenon may be used. Other sputtering method such as magnetron sputtering may be used instead of the ECR sputtering method. The ECR sputtering method has the advantage that the gate insulating film 11 can be formed at a lower temperature and higher pressure than in other sputtering methods.

The flow rates of argon gas, oxygen gas, and nitrogen gas are not limited to the above ranges. However, when they fall within the above ranges, the gate insulating film 11 can be formed with good controllability of oxygen composition ratio x and nitrogen composition ratio y in ZrOₓN_{y}.

Under the above conditions, the gate insulating film 11 can be formed so that the oxygen composition ratio x and the nitrogen composition ratio y of the gate insulating film 11 satisfy the following conditions: x>0, y>0, 0.3≦y/x≦10, and 1.5≦0.55x+y≦1.7, and the gate insulating film 11 can be formed in amorphous state.

According to the inventors' studies, it was found that a ZrOₓN_{y} film, in which the oxygen composition ratio x and the nitrogen composition ratio y were outside a range of 1.5≦0.55x+y≦1.7, could not be formed even if the respective flow rates of argon gas, nitrogen gas and oxygen gas in the ECR sputtering method were varied if only the above temperature and pressure conditions were satisfied. From this, when an amorphous ZrOₓN_{y} film can be formed by the ECR sputtering method under the conditions of the present invention, the ZrOₓN_{y} film is considered to have an oxygen composition ratio x and an nitrogen composition ratio y satisfying 1.5≦0.55x+y≦1.7.

Since the gate insulating film 11 is formed in amorphous state, the semiconductor layer 10 does not need to be lattice-matched. Therefore, it can be formed on a SiO₂ insulating film or a compound semiconductor layer such as Group III-V compound semiconductor, Group II-VI compound semiconductor, and Group III nitride semiconductor instead of the Si semiconductor layer 10.

When the ratio of oxygen gas flow rate to the ratio of nitrogen gas flow rate, i.e., the oxygen gas flow rate/the nitrogen gas flow rate, is from 0.012 to 0.36 in the ECR sputtering method under the above conditions, the gate insulating film 11 can be formed so as to suppress fluctuation in threshold voltage below 1 V. Particularly when the ratio of oxygen gas flow rate to nitrogen gas flow rate is from 0.036 to 0.36, fluctuation in threshold voltage can be further suppressed below 0.1 V.

Next, a gate electrode 12 was formed by a lift-off method in a specified region on the gate insulating film 11. More specifically, a resist film was formed by photolisography in a region other than the specified region on the gate insulating film 11. Then, an electrode film was formed by deposition on the specified region and the resist film. Subsequently, the resist film and a part of the electrode film thereon were removed by a lift-off method so that the electrode film remains only in the specified region, thus forming the gate electrode 12 only in the specified region on the gate insulating film 11. Through the above, the MIS type semiconductor device according to Embodiment 1 as shown in FIG. 1 was produced.

Through the above-mentioned production method of the MIS type semiconductor device according to Embodiment 1, the ZrOₓN_{y} amorphous gate insulating film 11 can be formed so as to have an oxygen composition ratio x and an nitrogen composition ratio y satisfying the following conditions: x>0, y>0, 0.3≦y/x≦10, and 1.5≦0.55x+y≦1.7. Therefore, even if the operating voltage is 5 V or more, fluctuation in threshold voltage can be suppressed, enabling stable operation.

The gate insulating film 11 formed by the above method can be kept in amorphous state even after heat treatment up to about 800° C., which realizes a high reliability of the device. Since the gate insulating film 11 is thermally stable, the threshold voltage of the MIS type semiconductor device according to Embodiment 1 is stable, and hardly fluctuates due to temperature change. Furthermore, thermal stability of the gate insulating film 11 allows less temperature constraints in a heat treatment process such as electrode alloying process after formation of the gate insulating film 11, thereby increasing the flexibility of the production process.

Specific evaluation of the MIS type semiconductor device according to Embodiment 1 will next be given as experimental examples.

### EXPERIMENTAL EXAMPLE 1

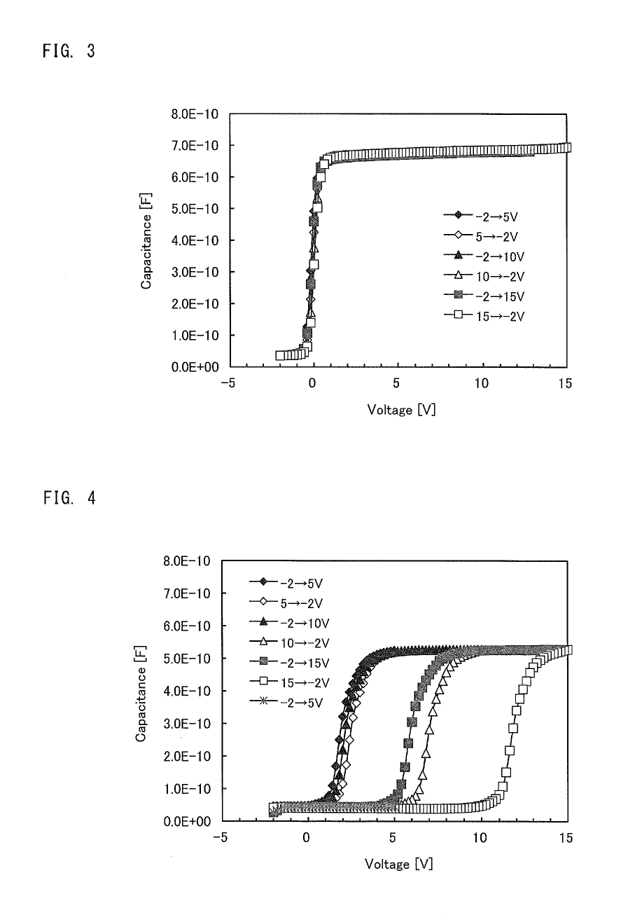

A MIS type semiconductor device according to Embodiment 1 having a gate insulating film 11 formed of amorphous ZrOₓN_{y} (here, x is 0.79 and y is 1.2) was produced, thereby to verify the thermal stability of threshold voltage. FIG. 3 is a graph showing the Capacitance-Voltage characteristic of the MIS type semiconductor device according to Embodiment 1. The applied voltage was varied by continuously sweeping the voltage from −2 V to 5 V, 5 V to −2 V, −2 V to 10 V, 10 V to −2 V, −2 V to 15 V, 15 V to −2 V, and −2 V to 5 V. The voltage sweep rate was 0.1 V/s. It is observed from FIG. 3 that the threshold voltage hardly fluctuates even if the applied voltage is swept as mentioned above. Particularly, even if the applied voltage is drastically varied from −2V to 15V, and 15V to −2V, the threshold voltage hardly fluctuates.

As a comparative example, the MIS type semiconductor device having the same structure as the device according to Embodiment 1 except that the gate insulating film 11 is formed of amorphous ZrO₂, was produced, thereby to verify the thermal stability of threshold voltage. FIG. 4 is a graph showing the Capacitance-Voltage characteristic of the MIS type semiconductor device according to the comparative example. The applied voltage was swept in the same way as in FIG. 3. As is obvious from FIG. 4, when the applied voltage is swept from −2 V to 10 V, 10 V to −2 V and from −2 V to 15 V, 15 V to −2 V, the threshold voltage drastically fluctuates. It is also obvious that when the applied voltage is swept from −2 V to 5 V and 5 V to −2 V, the threshold voltage slightly fluctuates.

Thus, the MIS type semiconductor device according to Embodiment 1 having a gate insulating film 11 formed of amorphous ZrOₓN_{y} (here, x and y satisfy the following conditions: x>0, y>0, 0.3≦y/x≦10, and 1.5<0.55x+y≦1.7) can be stably operated with no fluctuation in threshold voltage even if a large voltage is applied. As is clear from the result of FIG. 3, it is effective for the MIS type semiconductor device with an operating voltage of 5 V or more, particularly 10V or more, and even the MIS type semiconductor device with such an operating voltage can be stably operated.

### EXPERIMENTAL EXAMPLE 2

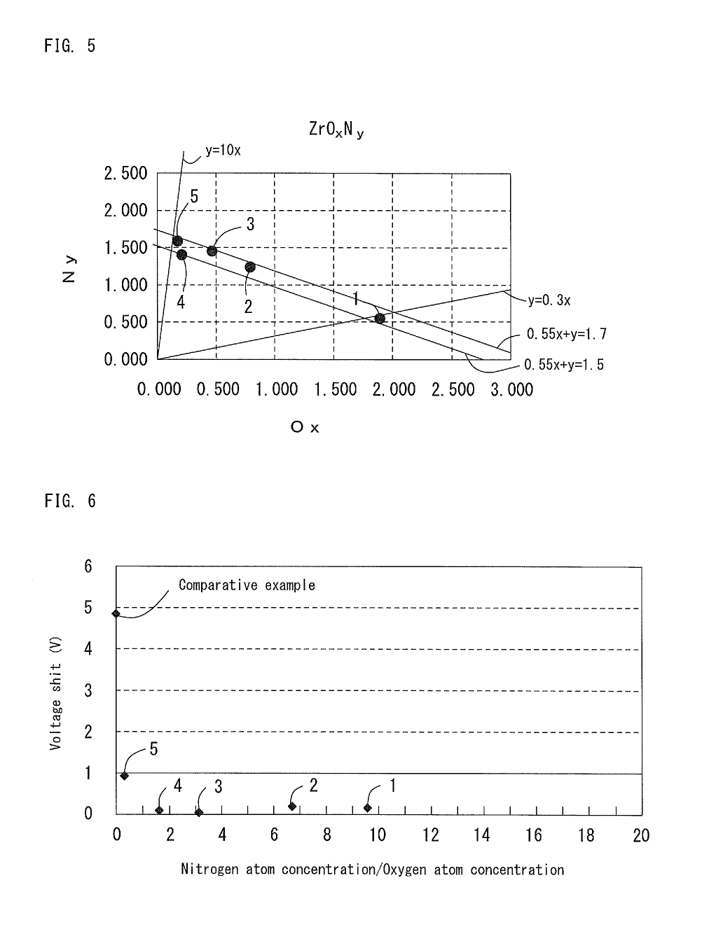

Five samples were produced at five different oxygen gas flow rates of 0.1, 0.3, 0.5, 1, and 3 sccm with an argon gas flow rate and a nitrogen gas flow rate maintained at 20 sccm and 8.5 sccm, respectively, in forming the gate insulating film 11 of the MIS type semiconductor device according to Embodiment 1. In all five samples, the gate insulating film 11 was formed in amorphous state. The oxygen composition ratio x and the nitrogen composition ratio y of the gate insulating film 11 were as shown in a graph of FIG. 5. That is, when the oxygen gas flow rate is 0.1 sccm (oxygen gas flow rate/nitrogen gas flow rate is 0.0118), x is about 0.2, and y is about 1.55 (plot 5 of FIG. 5). When the oxygen gas flow rate is 0.3 sccm (oxygen gas flow rate/nitrogen gas flow rate is 0.0353), x is about 0.24, and y is as about 1.4 (plot 4 of FIG. 5). When the oxygen gas flow rate is 0.5 sccm (oxygen gas flow rate/nitrogen gas flow rate is 0.0588), x is about 0.45, and y is about 1.45 (plot 3 of FIG. 5). When the oxygen gas flow rate is 1 sccm (oxygen gas flow rate/nitrogen gas flow rate is 0.1176), x is about 0.76, and y is about 1.24 (plot 2 of FIG. 5). When the oxygen gas flow rate is 3 sccm (oxygen gas flow rate/nitrogen gas flow rate is 0.3529), x is about 1.85, and y is about 0.55 (plot 1 of FIG. 5).

As is clear from the graph of FIG. 5, in all five samples, the oxygen composition ratio x, and the nitrogen composition ratio y of the gate insulating film 11 fall within a range wherein y has a range of ±0.1 with a straight line of 0.55x+y=1.6 as a center, that is, a range satisfying 1.5≦0.55x+y≦1.7.

FIG. 6 is a graph showing the threshold voltage shift of five samples used in FIG. 5, when the applied voltage was swept from −2V to 10 V, 10 V to −2 V, and −2 V to 15 V. The horizontal axis represents nitrogen atom concentration/oxygen atom concentration (i.e. y/x) of ZrOₓN_{y} which is the material of the gate insulating film 11, and the vertical axis represents the threshold voltage shift (V). Moreover, as a comparative example, the threshold voltage shift was measured by sweeping the applied voltage in the same way in the case where y/x=0, that is, the gate insulating film 11 is formed of ZrO₂. The numerals assigned to the plots of FIG. 6 correspond to the numerals assigned to the plots of FIG. 5. Whereas the threshold voltage shift was about 4.8 V in the comparative example in the case where the gate insulating film 11 is formed of ZrO₂, the threshold voltage shift was 1 V or less in other five samples. Thus, it was found that the composition ratio of nitrogen to oxygen y/x of ZrOₓN_{y} falls at least within a range of 0.3≦y/x≦10, the threshold voltage shift is 1 V or less. When the threshold voltage shift is 1 V or less, the MIS type semiconductor device according to Embodiment 1, in which an operating voltage is 5 V or more, particularly 10 V or more, can be stably operated. The reason why the ratio y/x was set to 10 or less is that as the nitrogen atom concentration of ZrOₓN_{y} increases, the properties of ZrOₓN_{y} become closer to those of conductive ZrN, and ZrOₓN_{y} cannot serve as an insulating film.

More preferably, y/x satisfies 1≦y/x≦5. When y/x falls within this range, the threshold voltage shift can be 0.1 V or less as shown in FIG. 6, thereby more stably operating the MIS type semiconductor device according to Embodiment 1.

The oxygen composition ratio x may be 0.5 or less. Even if x falls within this range, when x and y satisfy the following conditions: x>0, y>0, 0.3≦y/x≦10, and, 1.5≦0.55x+y≦1.7, the threshold voltage shift can be 1 V or less in the MIS type semiconductor device according to Embodiment 1 as shown in FIG. 6, thereby achieving stable operation.

The MIS type semiconductor device of the present invention is not limited to the structure shown in Embodiment 1. It may have any structure so long as a gate insulating film and a gate electrode are sequentially formed on the semiconductor layer.

In the MIS type semiconductor device according to Embodiment 1, the gate insulating film 11 is a single layer. However, it may comprise a plurality of layers having different oxygen composition ratios x and nitrogen composition ratios y so long as it is formed of amorphous ZrOₓN_{y} satisfying the above range of x and y.

### Embodiment 2

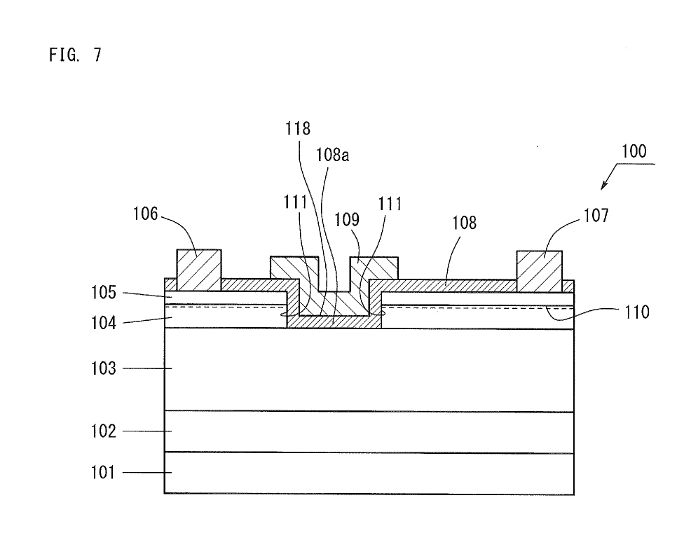

FIG. 7 shows the configuration of a HFET (Heterostructure Field-Effect Transistor) 100 according to Embodiment 2.

The HFET 100 includes a Si substrate 101; an AlN buffer layer 102 provided on the substrate 101; and a first carrier transport layer 103 formed of undoped GaN and provided on the AlN buffer layer 102.

Two separate second carrier transport layers 104 formed of undoped GaN are provided on two separate regions of the first carrier transport layer 103. Carrier supply layers 105 formed of Al_{0.25}Ga_{0.75}N are respectively provided on the two separate second carrier transport layers 104. The second carrier transport layer 104 and the carrier supply layer 105 form a heterojunction therebetween. The second carrier transport layer 104 and the carrier supply layer 105 are respectively formed through selective crystal re-growth.

A source electrode 106 is formed on one of the two separate carrier supply layers 105, and a drain electrode 107 is formed on the other carrier supply layer 105. Each of the source electrode 106 and the drain electrode 107 is formed of Ti/Al (Ti and Al are sequentially provided on the carrier supply layer 105).

An insulating film 108 formed of amorphous ZrOₓN_{y} (here, x and y satisfy the following conditions: x>0, y>0, 0.3≦y/x≦10, and 1.5≦0.55x+y≦1.7) is provided on a region of the first carrier transport layer 103 which is located between two separate stacked structures each including the second carrier transport layer 104 and the carrier supply layer 105, and on which the second carrier transport layer 104 is not provided. The insulating film 108 is also provided on two mutually facing lateral end surfaces 111 of the two stacked structures each including the second carrier transport layer 104 and the carrier supply layer 105, and is also provided on the carrier supply layers 105.

A gate electrode 109 is provided, via the insulating film 108, on a region of the first carrier transport layer 103 on which the second carrier transport layer 104 is not provided and on the two lateral end surfaces 111. The gate electrode 109 is formed of Ni/Au (Ni and Au are sequentially provided on the insulating film 108). The gate electrode 109 is also provided, via the insulating film 108, on the carrier supply layers 105 in the vicinity of the lateral end surfaces 111 such that the gate electrode 109 extends 0.5 μm from the lateral end surfaces 111 toward the source electrode 106 and the drain electrode 107, respectively. When the gate electrode is provided so as to extend in this manner, in the case where positive voltage is applied to the gate electrode 109, a larger amount of electrons can be accumulated in the vicinity of the lateral end surfaces 111, and the concentration of 2DEG can be further increased in a region located below the thus-extended gate electrode 109. Therefore, on-state resistance can be further reduced.

The first carrier transport layer 103 has a thickness of 2 μm; the second carrier transport layer 104 has a thickness of 100 nm; the carrier supply layer 105 has a thickness of 25 nm; and the insulating film 108 has a thickness of 40 nm. The distance between the source electrode 106 and the gate electrode 109 is 1.5 μm, and the distance between the gate electrode 109 and the drain electrode 107 is 6.5 μm; i.e., the HFET 100 has an asymmetric configuration in which the gate electrode 109 is provided proximal to the source electrode 106. Thus, the gate electrode 109 is located nearer to the source electrode 106 than to the drain electrode 107 for the purpose of improving breakdown voltage.

The substrate 101 may be formed of, in place of Si, any known material which has been conventionally used in a growth substrate for a Group III nitride semiconductor (e.g., sapphire, SiC, ZnO, spinel, or GaN).

The buffer layer 102 may be formed of GaN in place of AlN, or may be formed of a plurality of layers (e.g., AlN/GaN). The first carrier transport layer 103 may be formed of any Group III nitride semiconductor, but is preferably formed of GaN, from the viewpoint of, for example, crystallinity. The first carrier transport layer 103 may be doped with an n-type impurity, or may be formed of a plurality of layers. The first carrier transport layer 103 may be formed directly on the substrate 101 without formation of the buffer layer 102.

The second carrier transport layer 104 is formed of GaN, and the carrier supply layer 105 is formed of AlGaN. However, each of the second carrier transport layer 104 and the carrier supply layer 105 may be formed of any Group III nitride semiconductor, so long as the bandgap of the Group III nitride semiconductor of the carrier supply layer 105 is larger than that of the Group III nitride semiconductor of the second carrier transport layer 104. For example, the second carrier transport layer 104 may be formed of InGaN, and the carrier supply layer 105 may be formed of GaN or AlGaN. The carrier supply layer 105 may be doped with impurity such as Si (i.e., n-type). The carrier supply layer 105 may have a cap layer thereon. The second carrier transport layer 104 and the first carrier transport layer 103 may be formed of the same Group III nitride semiconductor material or different Group III nitride semiconductor materials.

By virtue of the heterojunction formed between the second carrier transport layer 104 and the carrier supply layer 105, a 2DEG layer (a portion shown by a dotted line in FIG. 7) is formed in the vicinity of the heterojunction interface 110 between the second carrier transport layer 104 and the carrier supply layer 105 and on the side of the second carrier transport layer 104. The second carrier transport layer 104 and the carrier supply layer 105 are formed on two regions separated by the gate electrode 109. Therefore, the 2DEG layer is formed in separate two regions; i.e., a region in which the source electrode 106 is formed on the carrier supply layer 105 (source-gate region) and a region in which the drain electrode 107 is formed on the carrier supply layer 105 (gate-drain region).

Each of the source electrode 106 and the drain electrode 107 is in ohmic contact with the second carrier transport layer 104 via the carrier supply layer 105 by means of the tunnel effect. Each of the source electrode 106 and the drain electrode 107 may be formed of, for example, Ti/Au in place of Ti/Al. Each electrode may be formed of a material for providing Schottky contact, but such a material is not preferred from the viewpoint of reduction in on-state resistance. For the purpose of attaining good ohmic contact, a region of the carrier supply layer 105 or the second carrier transport layer 104 directly below the source electrode 106 or the drain electrode 107 may be doped with Si at high concentration, or the thickness of the carrier supply layer 105 directly below the source electrode 106 or the drain electrode 107 may be reduced.

The insulating film 108 serves as both a gate insulating film and a protective film. The gate insulating film is the film of a region 108a of the insulating film 108, which is enclosed by the first carrier transport layer 103, the second carrier transport layer 104, the carrier supply layer 105, and the gate electrode 109. Needless to say, the insulating film may not serve as both a gate insulating film and a protective film. The protective film may be formed of other material, so long as the gate insulating film is formed of amorphous ZrOₓN_{y} (here, x and y satisfy the following conditions: x>0, y>0, 0.3≦y/x≦10, and, 1.5≦0.55x+y≦1.7). When the protective film is formed of other material, SiO₂, SiNₓ, Al₂O₃, HfO₂, ZrO₂, AlN or similar materials can be used. Although the insulating film 108 is formed of a single layer, a portion or the entirety of the insulating film 108 may be formed of a plurality of layers containing an amorphous ZrOₓN_{y}layer satisfying the above x and y conditions.

The gate electrode 109 may be formed of, for example, Ti/Al, W or polysilicon in place of Ni/Au.

The operation of HFET 100 according to Embodiment 2 will be next described. In the HFET 100, when bias voltage is not applied to the gate electrode 109, the 2DEG layers separated in the source-gate region and the gate-drain region are not electrically connected. Therefore, current does not flow between the source electrode and the drain electrode (i.e., OFF state). Thus, the HFET 100 exhibits a normally-off characteristic. Meanwhile, when a bias voltage equal to or higher than the threshold voltage is applied to the gate electrode 109, electrons are accumulated in a region which is in contact with the gate electrode 109 via the insulating film 108; specifically, in the vicinity of the surface of the first carrier transport layer 103 on which the second carrier transport layer 104 is not provided, and in the vicinity of mutually facing lateral end surfaces 111 of the second carrier transport layers 104 and the carrier supply layers 105. By means of the thus-accumulated electrons, the 2DEG layer located in the source-gate region is electrically connected to the 2DEG layer located in the gate-drain region. As a result, current flows between the source electrode and the drain electrode (i.e., ON state).

In the HEIST 100, since the second carrier transport layer 104 is selectively re-grown on the first carrier transport layer 103, impurities are incorporated at the interface between the first carrier transport layer 103 and the second carrier transport layer 104. However, the amount of re-growth-associated impurities contained in the second carrier transport layer 104 is reduced in accordance with increasing distance from the interface between the first carrier transport layer 103 and the second carrier transport layer 104. Therefore, virtually no re-growth-associated impurities are observed at the heterojunction interface 110 between the second carrier transport layer 104 and the carrier supply layer 105. Since the carrier supply layer 105 is continuously grown on the second carrier transport layer 104 after re-growth of the second carrier transport layer 104, flatness of the heterojunction interface 110 between the second carrier transport layer 104 and the carrier supply layer 105 is higher than that of the heterojunction interface between the first carrier transport layer 103 and the carrier supply layer 105 in the case where the carrier supply layer 105 is grown directly on the first carrier transport layer 103. Therefore, there is no reduction in the mobility of 2DEG generated in the vicinity of the heterojunction interface 110 between the second carrier transport layer 104 and the carrier supply layer 105 and on the side of the second carrier transport layer 104. Thus, the HFET 100 according to Embodiment 2 exhibits a normally-off characteristic and low on-state resistance.

From the viewpoints of sufficient reduction in amount of re-growth-associated impurities at the heterojunction interface between the second carrier transport layer 104 and the carrier supply layer 105, as well as improvement of flatness of the interface, the thickness of the second carrier transport layer 104 is preferably 50 nm or more.

In the HFET 100, the thickness of the insulating film 108 is adjusted to be smaller than that of the second carrier transport layer 104 so that the level of the top surface 118 of the region 108a in the insulating film 108 formed on the first carrier transport layer 103 is below that of the heterojunction interface 110 between the second carrier transport layer 104 and the carrier supply layer 105; i.e., the top surface 118 is nearer to the first carrier transport layer 103 than the heterojunction interface 110 is. With this structure, when positive voltage is applied to the gate electrode 109, a larger amount of electrons can be accumulated in the vicinity of the two lateral end surfaces 111. As a result, on-state resistance can be further reduced.

In the HFET 100, the gate insulating film (region 108a of the insulating film 108, which is enclosed by the first carrier transport layer 103, the second carrier transport layer 104, the carrier supply layer 105, and the gate electrode 109) is formed of amorphous ZrOₓN_{y} (here, x and y satisfy the following conditions: x>0, y>0, 0.3≦y/x≦10, and 1.5≦0.55x+y≦1.7). Therefore, even if the operating voltage of the HFET 100 is 5V or more, the threshold voltage does not fluctuate, thereby achieving stable operation.

Next will be described a method for producing the HFET 100 according to Embodiment 2 with reference to the drawings.

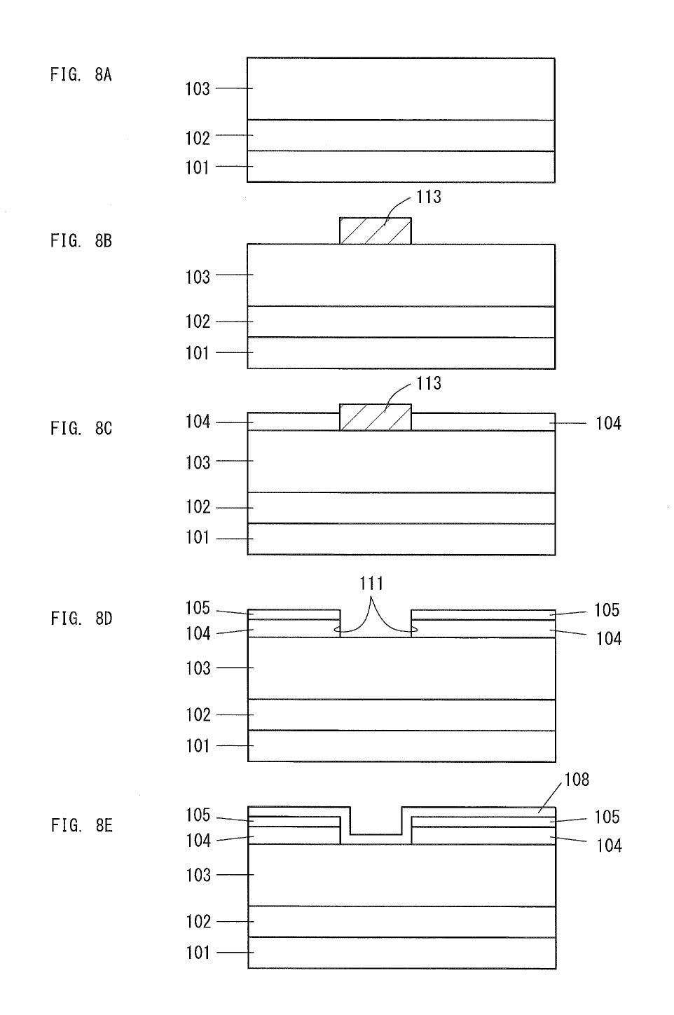

Firstly, an AlN buffer layer 102 was formed on a Si substrate 101 by MOCVD method. Then, a first carrier transport layer 103 was formed from undoped GaN on the buffer layer 102 by MOCVD method (FIG. 8A). The gases employed were as follows: hydrogen and nitrogen as carrier gases; ammonia gas as a nitrogen source; TMG (trimethylgallium) as a Ga source; and TMA (trimethylaluminum) as an Al source.

Subsequently, a SiO₂ mask 113 was formed on a specific region of the first carrier transport layer 103 by CVD method, and the mask 113 was not formed on two regions separated by the mask 113, to thereby expose the surface of the first carrier transport layer 103 (FIG. 8B). No particular limitation is imposed on the material of the mask 113, so long as the material inhibits growth of a Group III nitride semiconductor. The mask 113 may be formed of, in place of SiO₂ film, an insulating film of, for example, Si₃N₄, Al₂O₃, HfO₂, or ZrO₂.

Next, a second carrier transport layer 104 formed of undoped GaN was re-grown on the first carrier transport layer 103 by MOCVD method. Since GaN is not grown on the mask 113, the second carrier transport layer 104 is selectively re-grown only on the two regions separated by the mask 113 (FIG. 8C). During this regrowth, flatness of the interface between the first carrier transport layer 103 and the second carrier transport layer 104 is degraded, and impurities are incorporated at the interface. However, as growth of the second carrier transport layer 104 proceeds, flatness of the growing surface of the layer 104 is improved, and density of re-growth-associated impurities on the growing surface is decreased.

After the second carrier transport layer 104 has been grown so as to have a specific thickness, an Al_{0.25}Ga_{0.75}N carrier supply layer 105 was successively grown thereon by MOCVD method. During this growth process, crystal growth on the mask 113 is also inhibited. Therefore, the carrier supply layer 105 is grown only on the two second carrier transport layers 104. When the growth of the carrier supply layer 105 is started, flatness of the surface of the second carrier transport layer 104, on which the carrier supply layer 105 is grown, has been already improved, and density of impurities on the surface has been decreased substantially to zero. Therefore, flatness of the heterojunction interface between the second carrier transport layer 104 and the carrier supply layer 105 is high, and virtually no re-growth-associated impurities are observed in the vicinity of the interface. After the carrier supply layer 105 has been grown so as to have a specific thickness, the mask 113 was removed (FIG. 8D).

Subsequently, an insulating film 108 of amorphous ZrOₓN_{y} (here, x and y satisfy the following conditions: x>0, y>0, 0.3≦y/x≦10, and 1.5≦0.55x+y≦1.7) was formed on a region of the first carrier transport layer 103 on which the second carrier transport layers 104 are not provided; on two mutually facing lateral end surfaces 111 of two separate stacked structures each including the second carrier transport layer 104 and the carrier supply layer 105; and on the carrier supply layers 105 (FIG. 8E). The insulating film 108 serves as both a gate insulating film and a protective film of the carrier supply layer 105 for common use to reduce the number of production processes thereby.

Here, the insulating film 108 is formed by ECR sputtering method, in a mixture gas of nitrogen and oxygen mixed in argon gas, using a Zr metal target, at a substrate temperature of room temperature (1° C. to 30° C.), a pressure of 0.07 Pa to 0.2 Pa, a RF power of 500 W, and a microwave power of 500 W. The argon gas flow rate is 15 sccm to 30 sccm, the oxygen gas flow rate is 0.1 sccm to 3.0 sccm, and the nitrogen gas flow rate is 4.3 sccm to 17 sccm. The oxygen composition ratio and the nitrogen composition ratio of the insulating film 108 can be adjusted by the oxygen gas flow rate and the nitrogen gas flow rate, respectively. The ratio of the oxygen gas flow rate to the nitrogen gas flow rate, i.e. ratio of the oxygen gas flow rate/the nitrogen gas flow rate, is from 0.012 to 0.36. Under these conditions, the insulating film 108 of amorphous ZrOₓN_{y} (here, x and y satisfy the following conditions: x>0, y>0, 0.3≦y/x≦10, and, 1.5≦0.55x+y≦1.7) can be formed.

Subsequently, the insulating film 108 was removed so as to expose regions of the carrier supply layer 105 on which a source electrode 106 and a drain electrode 107 are formed, and the source electrode 106 and the drain electrode 107 were formed on the thus-exposed regions of the carrier supply layer 105 through vapor deposition and the lift-off process. A gate electrode 109 was formed on a portion of the insulating film 108, through vapor deposition and the lift-off process, the portion including an area above a region of the first carrier transport layer 103 on which the second carrier transport layer 104 is not provided; two front areas of the two lateral end surfaces 111; and an area above the carrier supply layer 105 in the vicinity of the lateral end surfaces 111. Thus, the HFET 100 shown in FIG. 7 was produced.

In the HFET 100 produced through this production method, flatness of the heterojunction interface between the second carrier transport layer 104 and the carrier supply layer 105 is improved, and virtually no re-growth-associated impurities are observed in the vicinity of the interface. Therefore, the HFET 100 exhibits a normally-off characteristic, and low on-state resistance. The insulating film 108 can be formed of amorphous ZrOₓN_{y} (here, x and y satisfy the following conditions x>0, y>0, 0.3≦y/x≦10, and 1.5≦0.55x+y≦1.7). Therefore, even if the operating voltage of the HFET 100 is 5V or more, the threshold value does not fluctuate, thereby achieving stable operation.

In the aforementioned production method for the HFET 100, the mask 113 employed for crystal growth is removed after formation of the carrier supply layer 105. However, the mask 113 may be left and employed as a gate insulating film of amorphous ZrOₓN_{y} (here, x and y satisfy the following conditions: x>0, y>0, 0.3≦y/x≦10, and 1.5≦0.55x+y≦1.7).

### Embodiment 3

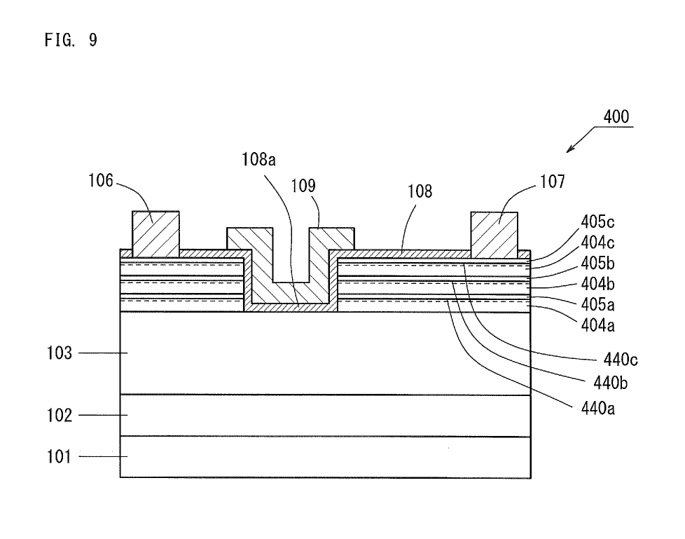

FIG. 9 shows the configuration of a HFET 400 according to Embodiment 3. The HFET 400 has the same configuration as the HFET 100 according to Embodiment 1, except that the second carrier transport layer 104 and the carrier supply layer 105 are replaced with three layer pairs each including a second carrier transport layer 404 and a carrier supply layer 405; specifically, a second carrier transport layer 404a, a carrier supply layer 405a, a second carrier transport layer 404b, a carrier supply layer 405b, a second carrier transport layer 404c, and a carrier supply layer 405c are sequentially deposited on the first carrier transport layer 103. Similar to the case of the second carrier transport layer 104 and the carrier supply layer 105 of the HFET 100, the three layer pairs of the second carrier transport layer 404 and the carrier supply layer 405 are formed on the first carrier transport layer 103 through selective re-growth.

2DEG layers are formed respectively at the heterojunction interface 440a between the second carrier transport layer 404a and the carrier supply layer 405a and on the side of the second carrier transport layer 404a; at the heterojunction interface 440b between the second carrier transport layer 404b and the carrier supply layer 405b and on the side of the second carrier transport layer 404b; and at the heterojunction interface 440c between the second carrier transport layer 404c and the carrier supply layer 405c and on the side of the second carrier transport layer 404c. Since the second carrier transport layer 404a is formed on the first carrier transport layer 103 through selective re-growth and the other second carrier transport layers 404b, 404c and the carrier supply layers 405a, 405b and 405c are formed on the second carrier transport layers 404a, 404b and 404c, respectively through selective re-growth, the heterojunction interfaces 440a, 440b, and 440c exhibit high flatness, and virtually no growth-associated impurities are incorporated at regions in the vicinity of the heterojunction interfaces 440a, 440b, and 440c. Therefore, reduction in mobility of 2DEG generated in the vicinity of the heterojunction interfaces 440a, 440b, and 440c is suppressed, and on-state resistance is reduced.

As described above, the HFET 400 according to Embodiment 3 has a structure including three 2DEG layers, in which reduction in mobility of 2DEG is suppressed. Therefore, the HFET 400 exhibits further reduced on-state resistance.

Similar to the case of the HFET 100 according to Embodiment 2, in the HFET 400 according to Embodiment 3, the insulating film 108 (a region 108a of the insulating film 108, which is enclosed by the first carrier transport layer 103, the second carrier transport layer 404, the carrier supply layer 405, and the gate electrode 109) is formed of amorphous ZrOₓN_{y} (here, x and y satisfy the following conditions x>0, y>0, 0.3≦y/x≦10, and 1.5≦0.55x+y≦1.7). Therefore, even if the operating voltage of the HFET 400 is 5V or more, the threshold voltage does not fluctuate, thereby achieving stable operation.

In Embodiment 3, the second carrier transport layers 404a, 404b, and 404c have the same composition, and the carrier supply layers 405a, 405b, and 405c have the same composition. However, the second carrier transport layers 404a, 404b, and 404c may have different compositions, and the carrier supply layers 405a, 405b, and 405c may have different compositions, so long as heterojunction interfaces are formed between the second carrier transport layer 404a and the carrier supply layer 405a, between the second carrier transport layer 404b and the carrier supply layer 405b, and between the second carrier transport layer 404c and the carrier supply layer 405c, and a 2DEG layer is formed in the vicinity of each of the heterojunction interfaces.

In Embodiments 2 and 3, the MIS type semiconductor device of the present invention is applied to a HFET. However, the present invention is not limited to this, and is applicable to any semiconductor device having a conventionally known MIS type structure. For example, the present invention is also applicable to, for example, a FET or an IGBT (insulating gate bipolar transistor).

The MIS type semiconductor device of the present invention is suitable for a power device such as MISFET and HFET.

What is claimed is:

1. A MIS type semiconductor device with an operating voltage of 5V or more comprising:
a gate insulating film formed of ZrOₓN_{y} on a semiconductor layer;
a gate electrode on the gate insulating film;
wherein the gate insulating film is in amorphous state; and
composition ratios x and y of the gate insulating film satisfy x>0, y>0, and 0.3≦y/x≦10.

2. The MIS type semiconductor device according to claim 1, wherein the composition ratios x and y further satisfy 1.5≦0.55x+y≦1.7.

3. The MIS type semiconductor device according to claim 2, wherein the composition ratios x and y satisfy 1≦y/x≦5.

4. The MIS type semiconductor device according to claim 3, wherein the composition ratio x satisfy 0.5.

5. The MIS type semiconductor device according to claim 4, wherein the gate insulating film is directly in contact with on the semiconductor layer.

6. The MIS type semiconductor device according to claim 5, wherein the semiconductor layer is a Group III nitride semiconductor layer.

7. The MIS type semiconductor device according to claim 6, wherein the operating voltage is 10 V or more.

8. A method for producing a MIS type semiconductor device, the method comprising:
forming a ZrOₓN_{y} gate insulating film on a semiconductor layer by sputtering method;
forming a gate electrode on the gate insulating film; and
wherein the gate insulating film is formed so as to be in amorphous state, and have composition ratios x and y satisfying x>0, y>0, and 0.3≦y/x≦10, using a Zr metal target, flowing a mixture gas comprising nitrogen gas and oxygen gas, at a room temperature in the sputtering method.

9. The method for producing the MIS type semiconductor device according to claim 8, wherein the composition ratios x and y further satisfy 1.5≦0.55x+y≦1.7.

10. The method for producing the MIS type semiconductor device according to claim 9, wherein the gate insulating film is formed so that the composition ratios x and y satisfy 1≦y/x≦5.

11. The method for producing the MIS type semiconductor device according to claim 10, wherein the gate insulating film is formed so as to satisfy the composition ratio x≦0.5.

12. The method for producing the MIS type semiconductor device according to claim 11, wherein the gate insulating film is formed directly on the semiconductor layer.

13. The method for producing the MIS type semiconductor device according to claim 12, wherein the semiconductor layer is a Group III nitride semiconductor layer.

14. The method for producing the MIS type semiconductor device according to claim 13, wherein the MIS type semiconductor device has an operating voltage of 5 V or more.

15. A method for producing a MIS type semiconductor device, the method comprising:
forming a ZrOₓN_{y} gate insulating film on a semiconductor layer by sputtering method;
forming a gate electrode on the gate insulating film;
wherein the gate insulating film is formed, using a Zr metal target, flowing a mixture gas comprising nitrogen gas and oxygen gas, at a room temperature in the sputtering method; and
wherein the ratio of oxygen gas flow rate to nitrogen gas flow rate is 0.012 to 0.36.

16. The method for producing the MIS type semiconductor device according to claim 15, wherein the ratio of oxygen gas flow rate to nitrogen gas flow rate is 0.036 to 0.36.

17. The method for producing the MIS type semiconductor device according to claim 16, wherein the nitrogen gas flow rate is 4.3 sccm to 17 sccm, and the oxygen gas flow rate is 0.1 sccm to 3.0 sccm.

18. The method for producing the MIS type semiconductor device according to claim 17, wherein the sputtering method is ECR sputtering method.

19. The method for producing the MIS type semiconductor device according to claim 18, wherein the gate insulating film is directly in contact with on the semiconductor layer.

20. The method for producing the MIS type semiconductor device according to claim 19, wherein the MIS type semiconductor device has a rated voltage of 5 V or more.
